(19) United States
(12) Patent Application Publication
(10) Pub. No.: US 2012/0068871 A1
(43) Pub. Date: Mar. 22, 2012

(54) AD CONVERTER-EQUIPPED TEMPERATURE SENSOR CIRCUIT AND SEMICONDUCTOR INTEGRATED CIRCUIT

(75) Inventors: Manabu WATANABE, Kyoto (JP); Minoru ITO, Shiga (JP)

(73) Assignees: PANASONIC CORPORATION, Osaka (JP); MAEDA PATENT OFFICE, Osaka (JP)

(21) Appl. No.: 13/308,155

(22) Filed: Nov. 30, 2011

Related U.S. Application Data
(63) Continuation of application No. PCT/JP2010/007259, filed on Dec. 14, 2010.

(30) Foreign Application Priority Data
Jul. 13, 2010 (JP) 2010-158968

(51) Int. Cl. H03M 1/38

(52) U.S. Cl. 341/161

(57) ABSTRACT

In an AD converter-equipped temperature sensor circuit, at start of operation, a successive approximation type AD converter converts an analog voltage having temperature dependence received from a voltage generation circuit, to determine all bits of the converted digital signal. Thereafter, a power control circuit detects only a change in the outputs of comparators into which reference voltages upwardly and downwardly adjacent to the potential of the analog voltage are input, and shuts off power supply to any comparator other than the above comparators. Thus, in sensing of a steady, slow-changing signal like the analog voltage having temperature dependence using the AD converter, power consumption is reduced and the signal processing time is shortened without degrading the resolution of the AD converter.

### CROSS-REFERENCE TO RELATED APPLICATION

This is a continuation of PCT International Application PCT/JP2010/007259 filed on Dec. 14, 2010, which claims priority to Japanese Patent Application No. 2010-158968 filed on Jul. 13, 2010. The disclosures of these applications including the specifications, the drawings, and the claims are hereby incorporated by reference in their entirety.

### BACKGROUND

The present disclosure relates to an AD converter-equipped temperature sensor circuit, and more particularly to measures taken to reduce the power consumption thereof.

In recent years, in semiconductor integrated circuits, efforts of integrating analog circuits and digital circuits into one chip are being made. In particular, integration of high-frequency circuits in the radio communication field into one chip is under active development. However, since high-frequency circuits have variations in temperature, fabrication process, power supply voltage, digital noise, etc., it is difficult for the circuits to satisfy the performance over the whole range of such variations. In particular, as for the gain characteristics of low noise amplifiers (LNA), mixers, power amplifiers (PA), etc., temperature-caused fluctuations pose a large problem.

In view of the above, a number of semiconductor integrated circuits have been conventionally developed that perform temperature compensation using an AD converter-equipped temperature sensor circuit. However, such semiconductor integrated circuits have a problem that power consumption increases with the operation of the AD converter.

To solve the problem of increase in power consumption, conventionally, an AD converter capable of changing the converted bit count is proposed in the art disclosed in Japanese Patent Publication No. 2008-193744, for example. Using such an AD converter, by changing the converted bit count appropriately depending on the temperature measurement result of the AD converter, for example, power consumption can be reduced during operation with a low bit count.

### SUMMARY

When the prior art described above is used for a temperature sensor circuit, the following problem occurs. In the prior art configuration, whether the temperature measurement result of the AD converter is less than a threshold is determined, and the converted bit count is changed depending on the determination result. This involves digital processing of performing bit adjustment by a DSP, and this increases the signal processing time. Moreover, the resolution of the AD converter deteriorates when the measurement result is less than the threshold.

In view of the problem described above, it is an objective of the present disclosure to provide a temperature sensor circuit in which, once temperature measurement has been performed by operating an AD converter, any component of the AD converter other than components required for sensing a temperature change is brought to a halt, thereby reducing power consumption.

The AD converter-equipped temperature sensor circuit of the present disclosure includes: a voltage generation circuit configured to generate an analog voltage dependent on temperature characteristics; a successive approximation type AD converter having a plurality of comparators configured to compare the analog voltage received from the voltage generation circuit with a plurality of different reference voltages; and a power control circuit configured to control the operation of the AD converter, wherein the power control circuit performs temperature measurement by operating all the comparators of the AD converter, and, after determination of values of all bits of a digital signal of the AD converter, shuts off power supply to a comparator other than comparators into which reference voltages upwardly and downwardly adjacent to the potential of the analog voltage output from the voltage generation circuit are input, to detect a change in outputs of the comparators into which reference voltages upwardly and downwardly adjacent to the potential of the analog voltage are input.

In the AD converter-equipped temperature sensor circuit described above, preferably, when having detected a change in the outputs of the comparators into which reference voltages upwardly and downwardly adjacent to the potential of the analog voltage are input, the power control circuit supplies power to all the comparators of the AD converter to operate the comparators again, to determine all the bit values of the digital signal.

In the AD converter-equipped temperature sensor circuit described above, preferably, the power control circuit increases the value of the digital signal by 1 when having detected a change in the output of the comparator into which a higher reference voltage out of the reference voltages upwardly and downwardly adjacent to the potential of the analog voltage is input, and decreases the value of the digital signal by 1 when having detected a change in the output of the comparator into which a lower reference voltage out of the reference voltages upwardly and downwardly adjacent to the potential of the analog voltage is input.

The semiconductor integrated circuit of the present disclosure is a semiconductor integrated circuit having the AD converter-equipped temperature sensor circuit described above, which includes a high-frequency circuit, wherein the high-frequency circuit receives a temperature sensing signal from the AD converter-equipped temperature sensor circuit.

In the semiconductor integrated circuit described above, preferably, the high-frequency circuit is a low noise amplifier or a mixer.

According to the present disclosure, once the AD converter for temperature sensing is operated to perform temperature measurement, to determine all the bits of the digital signal of the AD converter, only a change in the outputs of comparators into which reference voltages upwardly and downwardly adjacent to the potential of the analog voltage are input is detected, shutting off power supply to any comparator other than the above comparators. Thus, power consumption can be reduced and, with no use of a DSP, the signal processing time can be shortened.

As described above, in the AD converter-equipped temperature sensor circuit of the present disclosure, temperature sensing for a steady, slow-changing analog voltage such as the analog voltage generated from the power generation circuit is performed using an AD converter as follows. Once the temperature is measured by operating the AD converter, power supply to any comparator other than comparators into which reference voltages upwardly and downwardly adjacent to the potential of the analog voltage are input is shut off, to allow only a change in the outputs of the comparators into which reference voltages upwardly and downwardly adjacent to the potential of the analog voltage are input to be detected. Therefore, power consumption can be reduced, and the processing time of the AD converter can be shortened.

### BRIEF DESCRIPTION OF THE DRAWINGS

FIG. 1 is a view showing a circuit configuration of a temperature sensor circuit equipped with a successive approximation type AD converter of the first embodiment of the present disclosure.

FIG. 2 is a view showing internal circuitry of a selector 1 in the temperature sensor circuit of FIG. 1.

FIG. 3 is a view showing internal circuitry of a selector 2 in the temperature sensor circuit of FIG. 1.

FIG. 4 is a view showing internal circuitry of a selector 3 in the temperature sensor circuit of FIG. 1.

FIG. 5 is a view showing internal circuitry of a selector 4 in the temperature sensor circuit of FIG. 1.

FIG. 6 is a view showing internal circuitry of a detection circuit in the temperature sensor circuit of FIG. 1.

FIG. 7 is a view showing internal circuitry of a control circuit in the temperature sensor circuit of FIG. 1.

FIG. 8 is a view showing a specific internal configuration of a voltage generation circuit in the temperature sensor circuit of FIG. 1.

FIG. 9 is a view showing an example of successive approximation operation of the successive approximation type AD converter in the temperature sensor circuit of FIG. 1.

FIGS. 10A and 10B illustrate the operation of the detection circuit, where FIG. 10A is a view showing a rise of a monitor bit signal and FIG. 10B is a view showing a fall of the monitor bit signal.

FIG. 11 is a view showing a configuration of a main portion of a temperature sensor circuit of the second embodiment of the present disclosure.

FIG. 12 is a view showing a circuit configuration of a temperature sensor circuit of the third embodiment of the present disclosure.

FIG. 13 is a view showing internal circuitry of a control circuit in the temperature sensor circuit of FIG. 12.

FIG. 14 is a view showing a schematic configuration of a semiconductor integrated circuit of the fourth embodiment.

### DETAILED DESCRIPTION

Embodiments of the present disclosure will be described hereinafter with reference to the accompanying drawings.

### First Embodiment

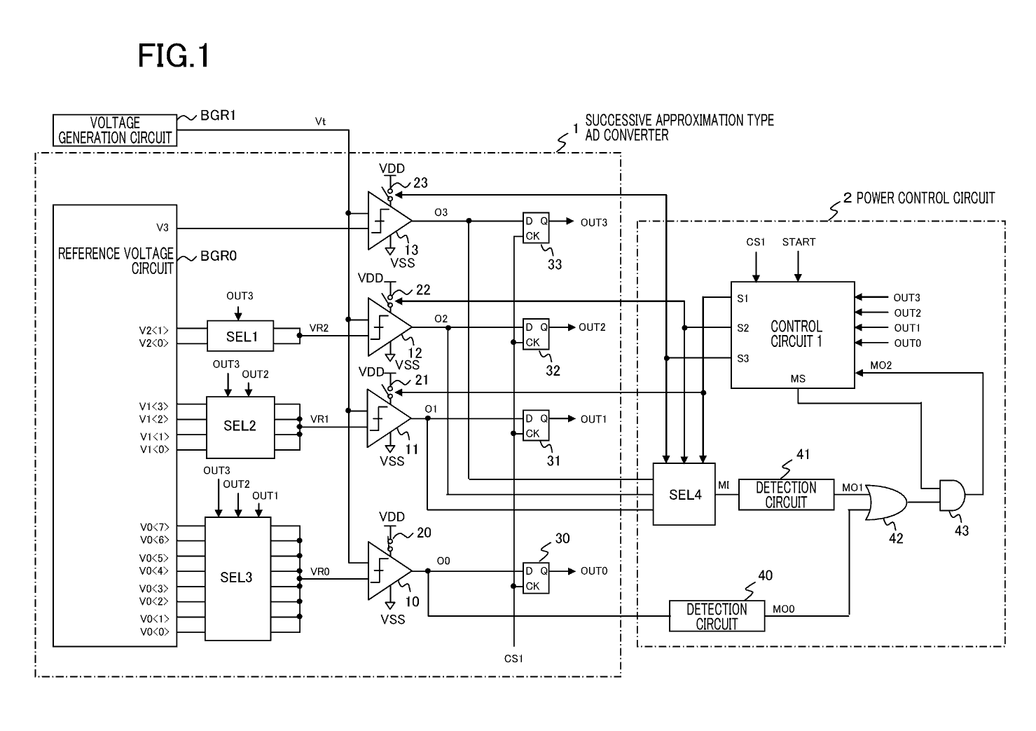

FIG. 1 is a view showing a specific circuit configuration of an AD converter-equipped temperature sensor circuit of the first embodiment of the present disclosure.

Referring to FIG. 1, the temperature sensor circuit includes a voltage generation circuit BGR1, a successive approximation type AD converter 1, and a power control circuit 2. Assume herein that the successive approximation type AD converter 1 converts data to a four-bit digital signal.

The AD converter 1 includes a reference voltage circuit BGR0 that generates reference voltages having no temperature dependence, three selectors SEL1-SEL3, four comparators 10-13, power supply switches 20-23 respectively placed between the comparators 10-13 and power supply VDD, four flipflop (FF) circuits 30-33 that respectively latch the outputs of the comparators 10-13.

The power control circuit 2 includes a detection circuit 40 connected to an output O0 of the comparator 10 corresponding to the least significant bit (LSB), a selector SEL4 connected to outputs O1-O3 of the other comparators 11-13, a detection circuit 41 connected to an output MI of the selector SEL4, an OR gate circuit 42 that performs logical operation of an output MO0 of the detection circuit 40 and an output MO1 of the detection circuit 41, an AND gate circuit 43 that receives an output signal of the OR gate circuit 42 and an output MS of a control circuit 1, and the control circuit 1. The control circuit 1 receives outputs OUT0-OUT3 of the four FF circuits 30-33 and an output signal MO2 of the AND gate circuit 43, and outputs signals S1-S3 to the power supply switches 21-23 for the three comparators 11-13 excluding the LSB comparator 10, out of the four comparators 10-13, and to the selector SEL4.

In addition to the above signals, the control circuit 1 also receives control signals START and CS1 issued at turn-on and at forced operation and outputs the signal MS to the AND gate circuit 43 for logical operation of the outputs MO0 and MO1 of the two detection circuits 40 and 41.

The four comparators 10-13 receive an analog voltage Vt from the voltage generation circuit BGR1 that generates an analog voltage having temperature dependence, as well as reference voltages VR0-VR2 and V3, respectively, from the reference voltage circuit BGR0 directly or via the selectors SEL1-SEL3, and output digital signals O0-O3, representing four bits totally, that respectively correspond to the magnitude relation of the analog voltage Vt with respect to the reference voltages VR0-VR2 and V3. The four FF circuits 30-33 respectively latch the digital signals O0-O3 with the control signal CS1, and output digital signals OUT0-OUT3 externally. The digital signals OUT0-OUT3 are also input into the selectors SEL1-SEL3, and the reference voltages VR0-VR2 determined based on the values of the digital signals OUT1-OUT3 are input into the comparators 10-12.

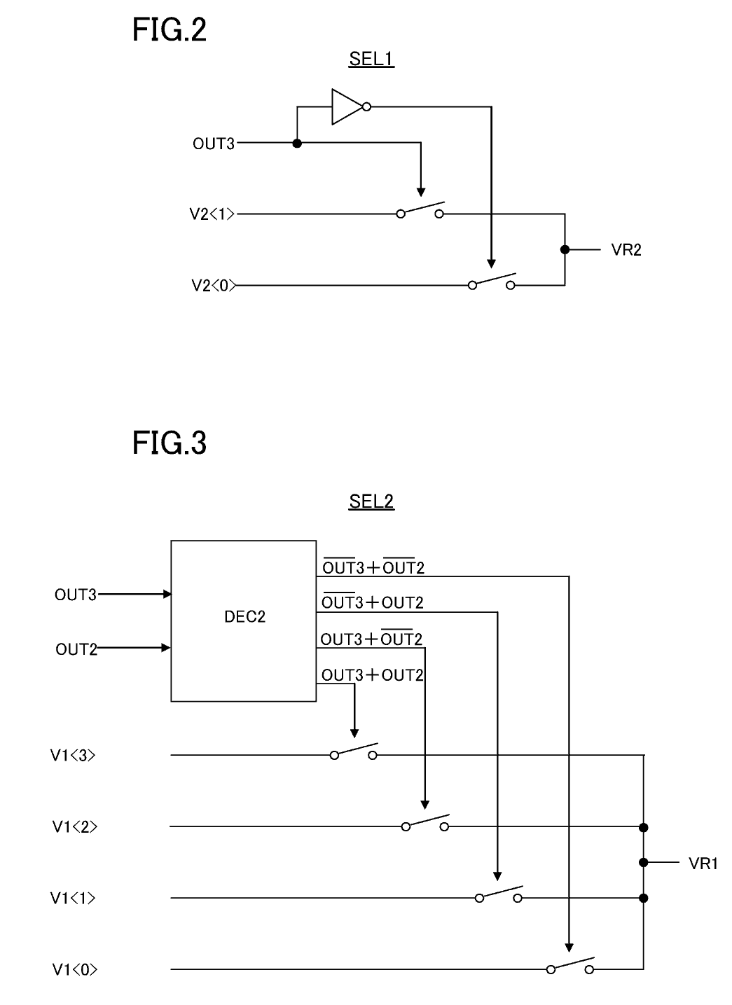

FIG. 2 shows internal circuitry of the selector SEL1. This circuit outputs, as the reference voltage VR2, a voltage V2<1> when the output signal OUT3 from the FF circuit 33 is high, and a voltage V2<0> when the output signal OUT3 is low.

FIG. 3 shows internal circuitry of the selector SEL2. This circuit, provided with a decoder DEC2, outputs, as the reference voltage VR1, a voltage V1<3> when both the output signal OUT3 from the FF circuit 33 and the output signal OUT2 from the FF circuit 32 are high, a voltage V1<2> when OUT3 is high and OUT2 is low, a voltage V1<1> when OUT3 is low and OUT2 is high, a voltage V1<0> when both OUT3 and OUT2 are low.

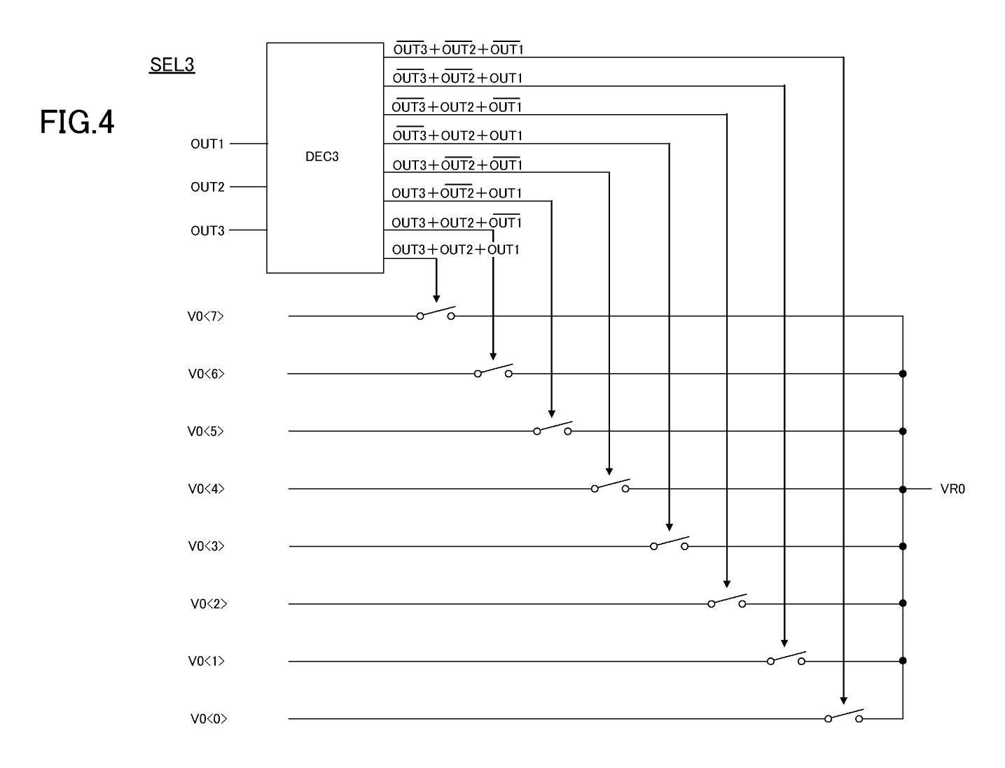

FIG. 4 shows internal circuitry of the selector SEL3. This circuit, provided with a decoder DEC3 as in the selector SEL2, selects, as the reference voltage VR0, any one of eight voltages V0<7> to V0<0> depending on whether the output signals OUT3, OUT2, and OUT1 from the FF circuits 31-33 are high or low. The logical expressions are shown in FIG. 4.

FIG. 5 shows internal circuitry of the selector SEL4. In this circuit, when one of the signals S1-S3 from the control circuit 1 goes high, one of the output signals OUT1-OUT3 of the FF circuits 31-33 corresponding to the high-level signal is selected as the output signal MI.

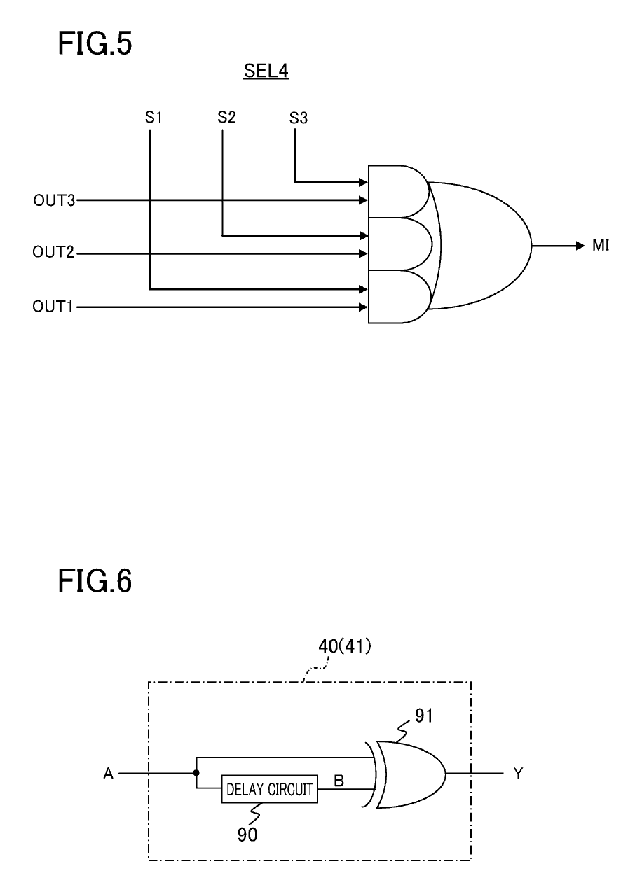

FIG. 6 shows internal circuitry of the detection circuits 40 and 41. As is found from FIG. 6, the detection circuit includes a delay circuit 90 and an EX-OR circuit 91.

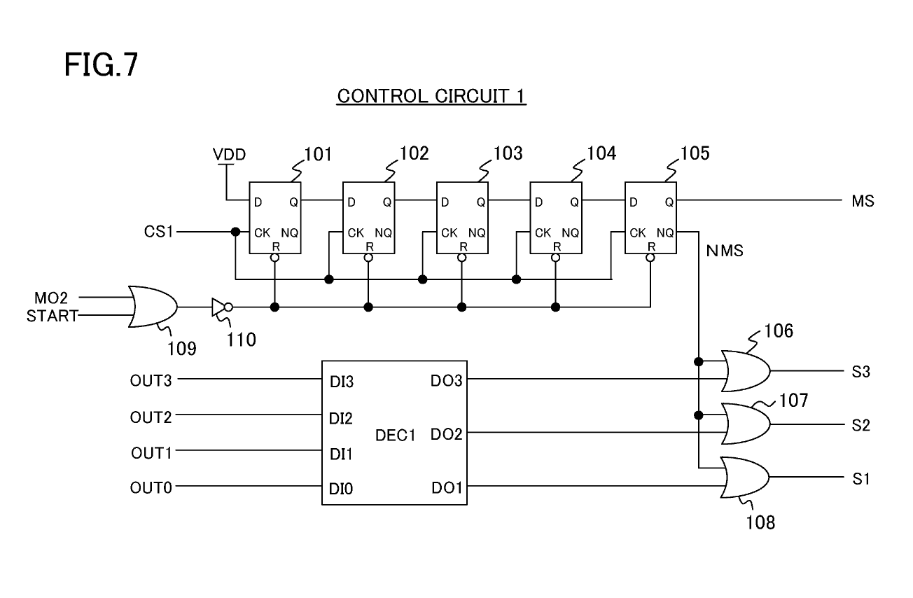

FIG. 7 shows internal circuitry of the control circuit 1. Assuming that, when the output signals S1-S3 of a decoder DEC1 are high, the corresponding power supply switches 21-23 are on, the output signals S1-S3 are represented by the following logical expressions.

S3=OUT3·NOUT2·NOUT1·NOUT0

S2=OUT2·NOUT1·NOUT0

S1=OUT1·NOUT0
where NOUT2 represents logical NOT of OUT2, NOUT1 represents logical NOT of OUT1, and NOUT0 represents logical NOT of OUT0.

In FIG. 7, when a high-level pulse is given in the output signal MO2 of the AND gate circuit 43 or the control signal START, five FF circuits 101-105 are reset, whereby the output signal MS of the FF circuit 105 goes low and an inverted output signal NMS thereof goes high. Since the inverted output signal NMS is input into three OR gate circuits 106-108, the output signals S1-S3 of the OR gate circuits 106-108 go high. When the fifth rising pulse is given in the control signal CS1, the output signal MS of the FF circuit 105 goes high and the inverted output signal NMS goes low. Therefore, output signals DO1-DO3 of the decoder DEC1 are output as they are as the output signals S1-S3 of the OR gate circuits 106-108.

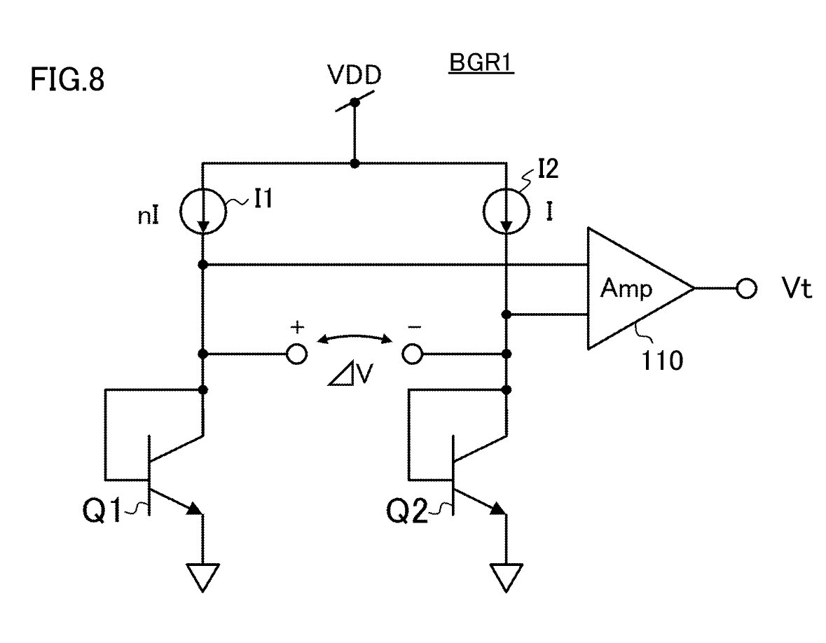

FIG. 8 shows a specific internal configuration of the voltage generation circuit BGR1. The voltage generation circuit BGR1 of FIG. 8 includes two collector-base connected bipolar transistors Q1 and Q2, current sources I1 and I2 that supply different current values nI and I to the transistors Q1 and Q2, and an amplifier 110 that amplifies the difference ΔV between the collector voltages of the transistors Q1 and Q2. The collector voltage difference ΔV between the transistors Q1 and Q2 has a temperature coefficient proportional to the absolute temperature T as represented by the following expression:

Temperature coefficient=k/q·1n(n)
where k is the Boltzmann constant (1.38×10⁻²³), q is the elementary charge (1.6×10⁻¹⁹), and n is a positive integer. The voltage generation circuit BGR1 makes use of this feature, and amplifies the collector voltage difference ΔV with the amplifier 110, to output the result as the analog voltage Vt having the temperature characteristics.

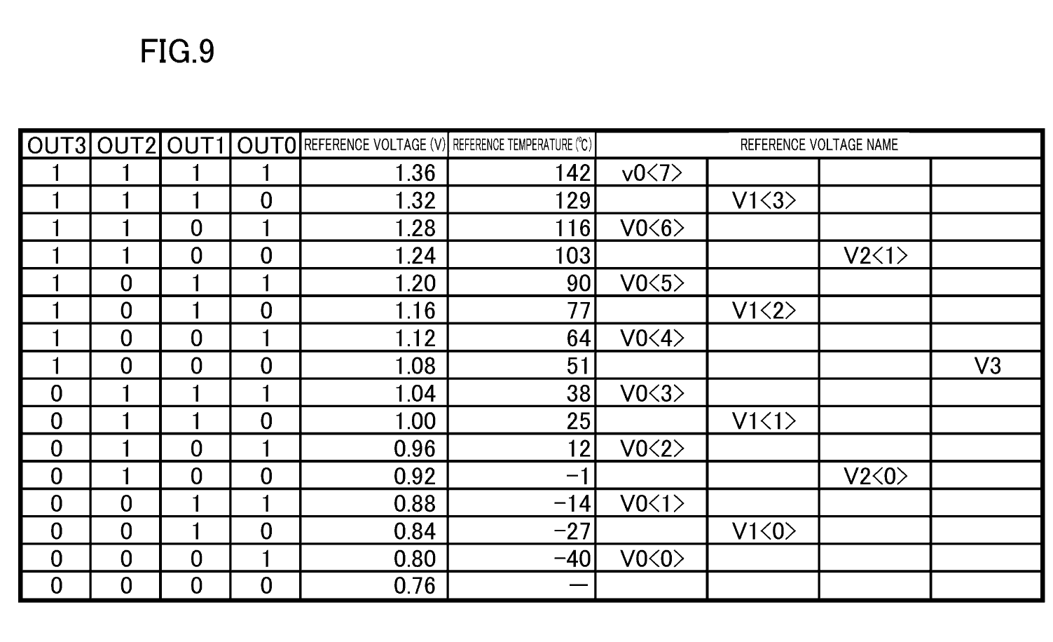

A specific example of the successive approximation operation of the AD converter 1 will be described hereinafter with reference to FIG. 9. First, the control circuit 1 of the power control circuit 2 turns on the power supply switches 20-23 for the comparators 10-13. Thereafter, the reference voltage circuit BGR0 supplies the reference voltage V3 (=1.08 V) to the comparator 13 corresponding to the most significant bit (MSB) out of all the four bits. The MSB comparator 13 compares the analog voltage Vt from the voltage generation circuit BGR1 with the reference voltage V3. The FF circuit 33 latches the comparison result with the control signal CS1 and outputs the digital signal OUT3.

Depending on the comparison result, 0 or 1, the selector SEL1 selects the reference voltage V2<0> (=0.92 V) or the reference voltage V2<1> (=1.24 V) of the reference voltage circuit BGR0, and supplies the selected reference voltage VR2 to the comparator 12 corresponding to the third bit. The comparator 12 compares the analog voltage Vt from the voltage generation circuit BGR1 with the selected reference voltage VR2 (e.g., V2<1>). The FF circuit 32 latches the comparison result with the control signal CS1 and outputs the digital signal OUT2.

Thereafter, depending on the comparison results, 0 or 1, the selector SEL2 selects the reference voltage V1<2> (=1.16 V) or the reference voltage V1<3> (=1.32 V) of the reference voltage circuit BGR0, and supplies the selected reference voltage VR1 to the comparator 11 corresponding to the second bit. The comparator 11 compares the analog voltage Vt from the voltage generation circuit BGR1 with the selected reference voltage VR1 (e.g., V1<2>). The FF circuit 31 latches the comparison result with the control signal CS1 and outputs the digital signal OUT1.

Subsequently, depending on the comparison results, 0 or 1, the selector SEL3 selects the reference voltage V0<4> (=1.12 V) or the reference voltage V0<5> (=1.20 V) of the reference voltage circuit BGR0, and supplies the selected reference voltage VR0 to the LSB comparator 10. The comparator 10 compares the analog voltage Vt from the voltage generation circuit BGR1 with the selected reference voltage VR0 (e.g., V0<5>). The FF circuit 30 latches the comparison result with the control signal CS1 and outputs the digital signal OUT0. Thus, the digital signals OUT0-OUT3 from the outputs of the comparators 10-13 corresponding to all the bits are determined.

Referring back to FIG. 1, the detection circuit 40 receives, as its input signal, the digital signal O0 of the comparator 10 corresponding to the LSB out of all the four bits as the output signals OUT0-OUT3. The detection circuit 41 receives, as its input signal, the digital signal MI that is any one (monitor bit) selected from the output signals O1-O3 of the three comparators 11-13 by the selector SEL4 based on the output signals S1-S3 of the control circuit 1. As shown in FIG. 6, the detection circuits 40 and 41 each include: a delay circuit 90 that receives the digital signal MI as the monitor bit or the LSB digital signal as an input signal A and delays the input signal by a predetermined time τ; and a 2-input exclusive OR (EX-OR) circuit 91 that receives an output signal B of the delay circuit 90 and the input signal A.

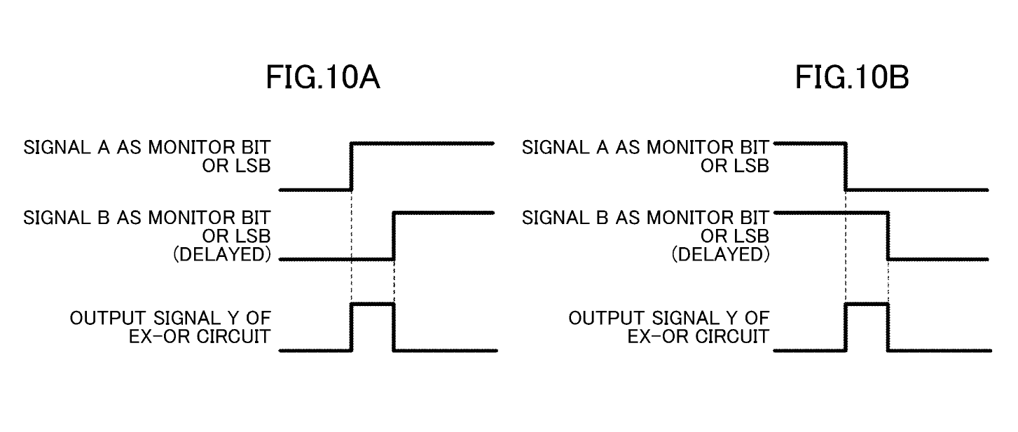

As shown in FIG. 1, the output signal MO0 of the detection circuit 40 and the output signal MO1 of the detection circuit 41 are input into the OR gate circuit 42, and the output signal of the OR gate circuit 42 is input into the AND gate circuit 43. The AND gate circuit 43 also receives the output signal MS of the control circuit 1 at the other input thereof, and the output signal MO2 of the AND gate circuit 43 is input into the control circuit 1. As already described, the output signal MS of the control signal 1 goes low when a high-level pulse is given in the output signal MO2 of the AND gate circuit 43 or the control signal START, and goes high when the fifth rising pulse is given in the control signal CS1. Therefore, the output signal MS serves to mask the outputs of the detection circuits 40 and 41 during the time of temperature measurement by the AD converter 1. In the detection circuits 40 and 41, an output signal Y of the EX-OR circuit 91 gives a high-level pulse at the time of a low to high rise of the digital signal A that is the output signal O0 (LSB) from the LSB comparator 10 or any one (monitor bit) selected from the output signals O1-O3 of the comparators 11-13 corresponding to the three MSBs by the selector SEL4 as shown in FIG. 10A and at the time of a high to low fall of the digital signal A as shown in FIG. 10B. Such a rise from low to high or fall from high to low of the digital signal as the LSB or the monitor bit occurs at the time when the analog voltage to be sensed becomes higher or lower than a reference voltage upwardly or downwardly adjacent to the potential thereof, as shown in the example of FIG. 9. For example, when the analog voltage Vt to be sensed is 1.21 V, a rise or a fall occurs when the analog voltage Vt becomes higher than the upwardly adjacent reference voltage V2<1> (=1.24 V) or lower than the downwardly adjacent reference voltage V0<5> (=1.20 V). In the example of FIG. 9, the resolution of the reference voltage is 0.04 V and the resolution of the corresponding temperature is 13° C.

In this embodiment, since the power supply switch 20 is always on, the control circuit 1 of the power control circuit 2 turns on the power supply switches 21-23 connected between the three MSB comparators 11-13 and the power supply VDD at the time of start of temperature measurement with the control signal START issued at power-on and at forced operation, to operate the four comparators 10-13, thereby starting analog-to-digital conversion by the AD converter 1.

Once the temperature measurement has been performed, the control circuit 1 of the power control circuit 2 receives the output signal of the EX-OR circuit 91 of the detection circuit 40 or 41. When the output signal is low, i.e., when the value of the digital signal of the comparator corresponding to the monitor bit or the LSB remains unchanged, the control circuit 1 turns off power supply switches connected between two comparators, corresponding to two bits, other than the two comparators of the AD converter 1 into which the reference voltages upwardly and downwardly adjacent to the potential of the analog voltage signal are input and the power supply voltage VDD, to halt the operation of these two comparators. For example, when the analog voltage Vt to be sensed output from the voltage generation circuit BGR1 is 1.10 V, the power supply switches 21 and 22 for the two comparators 11 and 12 other than the two comparators 10 and 13 into which two reference voltages V0<4> (=1.12 V) and V3 (=1.08 V) upwardly and downwardly adjacent to the potential of the analog voltage are input are turned off.

Thereafter, when either the output signal MO0 or MO1 of the EX-OR circuit 91 of the detection circuit 40 or 41 goes high, i.e., when a change is detected in the output of either of the two comparators into which the two reference voltages upwardly and downwardly adjacent to the potential of the analog voltage Vt to be sensed are input, the control circuit 1 of the power control circuit 2, receiving the output signal MO0 or MO1, turns on the power supply switches for the two comparators that are at rest to restart the operation of these comparators, thereby controlling to perform AD conversion again using all the four comparators 10-13 and determine the digital signals as all the four bits.

Therefore, in the first embodiment, all the comparators 10-13 of the AD converter 1 are operated at the start of operation, to perform temperature measurement. Thereafter, as far as the temperature does not become higher or lower than reference temperatures upwardly and downwardly adjacent to the sensed temperature, the operation of comparators, corresponding to two bits, other than the two comparators into which the reference voltages upwardly and downwardly adjacent to the potential of the analog voltage are input is halted by turning off the corresponding power supply switches. Thus, while the high resolution of the AD converter 1 using all the four bits is maintained, the power consumption of the AD converter 1 can be reduced effectively. Also, with no use of a DSP unlike the conventional case, the signal processing time can be shortened.

In the above description, the power supply switches 20-23 are respectively placed on the power supply voltage paths to the comparators 10-13 of the AD converter 1, and the operations of the comparators 10-13 are halted by turning off the power supply switches 20-23. Also, the output values of the comparators 10-13 are respectively held in the FF circuits 30-33 with the control signal CS1. It is however possible to adopt other circuit configurations.

Although the resolution of the AD converter 1 is four bits in the above description, the present disclosure is not limited to this. The resolution may naturally be three or more bits.

### Second Embodiment

An AD converter-equipped temperature sensor circuit of the second embodiment of the present disclosure will be described.

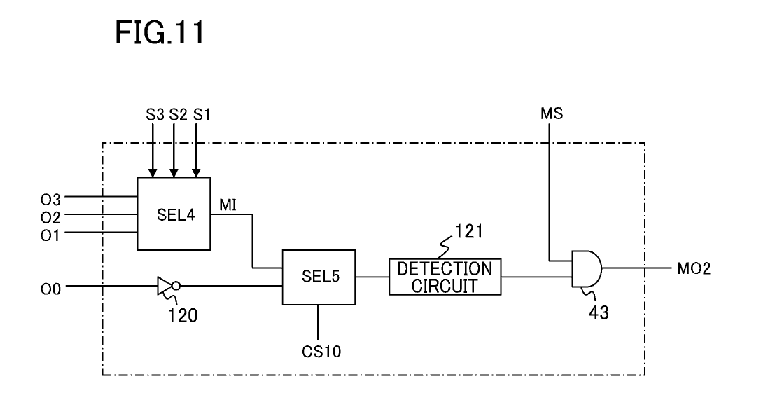

In the second embodiment, the operation of the two detection circuits 40 and 41 in the first embodiment described with reference to FIG. 1 is implemented by one detection circuit under time-sharing operation. The circuit configuration, operation, and effect of the temperature sensor circuit of this embodiment except for the above feature are the same as those in the first embodiment. FIG. 11 shows a specific circuit configuration of the portion different from the first embodiment.

Referring to FIG. 11, a selector SEL5 outputs the output signal MI of the selector SEL4 and an output of an inverter 120 that inverts the output signal O0 of the LSB comparator 10 in a time-sharing manner using the high and low levels of a control signal CS10. Since the output signal MI of the selector SEL4 and the output signal O0 of the comparator 10 are digital signals from the comparators into which the reference voltages upwardly and downwardly adjacent to the potential of the analog voltage signal to be sensed are input, they are in different voltage levels from each other: when one is low, the other is high. By inverting one of these digital signals, therefore, the voltage level remains unchanged when the selector SEL5 changes the signal from one to the other, and thus no malfunction will occur in a common detection circuit 121.

In FIG. 11, the output signal MI of the selector SEL4 and the inverted output of the output signal O0 of the LSB comparator 10 are input into the selector SEL5. Alternatively, it is naturally possible to input an inverted output of the output signal MI of the selector SEL4 and the output signal O0 of the LSB comparator 10 into the selector SEL5.

### Third Embodiment

An AD converter-equipped temperature sensor circuit of the third embodiment of the present disclosure will be described.

In the first embodiment, once a change in the output of a comparator is detected by the detection circuit 40 or 41, temperature measurement is started again from the beginning. In this embodiment, however, the states of digital signals after the temperature measurement are determined by computation, using the states of the digital signals before the temperature detection as references, based on the direction of the change of the analog voltage signal that has changed in association with the temperature.

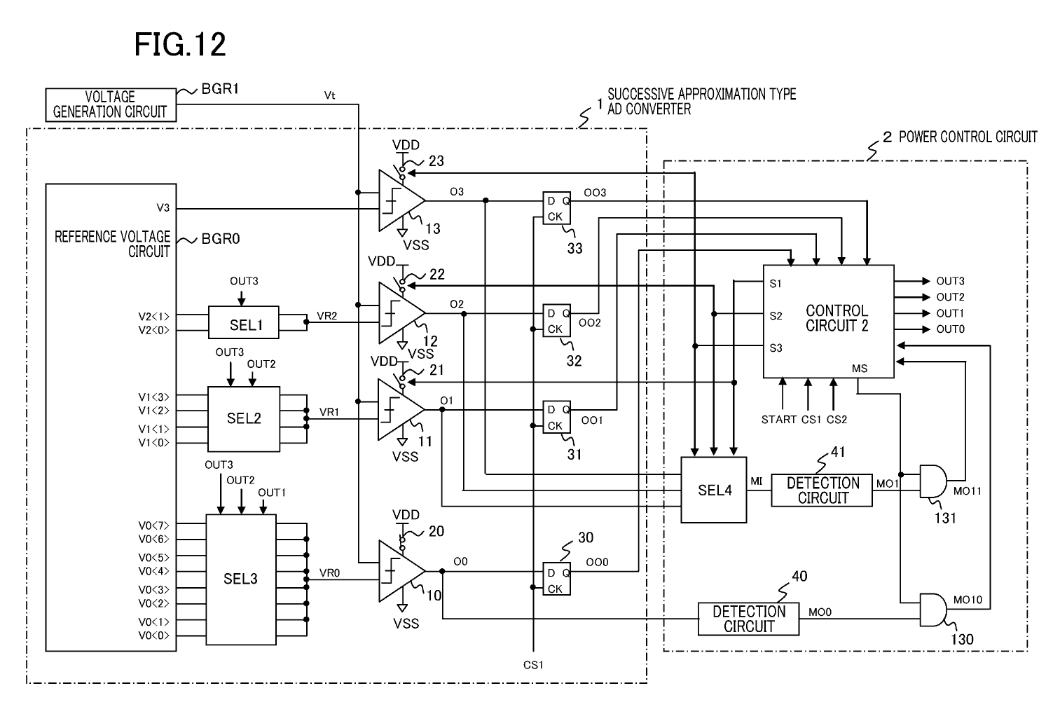

FIG. 12 shows a specific internal configuration of the AD converter-equipped temperature detection circuit of the third embodiment. The temperature detection circuit of this embodiment is different from the first embodiment described with reference to FIG. 1 in the configuration of the power control circuit 2 and in that the power control circuit 2 performs computation on the digital signals from the AD converter 1 and outputs the results externally. Note that, in FIG. 12, the same components as those in FIG. 1 are denoted by the same reference characters.

In the third embodiment, as shown in FIG. 12, the output signals O0-O3 of the comparators 10-13 are latched by the FF circuits 30-33, respectively, with the control signal CS1, and output signals OO0-OO3 of the FF circuits 30-33 are input into a control circuit 2. Also, the output signal MOO of the detection circuit 40 and the output signal MO1 of the detection circuit 41 are input into the control circuit 2 via AND gate circuits 130 and 131, respectively. The output signal MS of the control circuit 2 is input into the other inputs of the two AND gate circuits 130 and 131.

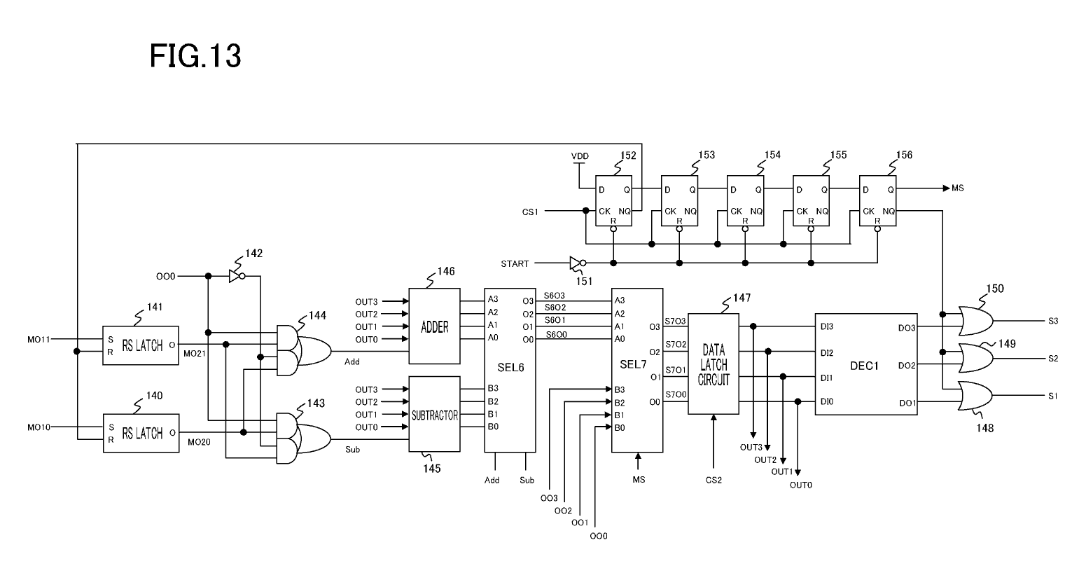

FIG. 13 shows a specific circuit configuration of the control circuit 2. RS latches 140 and 141 respectively latch the output signals MO10 and MO11 of the AND gate circuits 130 and 131, and output signals MO20 and MO21. Thereafter, two composite gate circuits 143 and 144 determine whether addition operation or subtraction operation should be performed from the relationship between the output OO0 of the FF circuit 30 for the LSB and the outputs MO20 and MO21 of the two RS latches 140 and 141 as follows.

Addition Operation Add=OO0·MO21+NOO0·MO20

Subtraction Operation Sub=OO0·MO20+NOO0·MO21
where NOO0 represents the logical NOT of OO0.

An adder 146 performs addition operation for the output signals OUT0-OUT3 using an addition output signal Add as the result of the determination by the above logical expression, and a subtractor 145 performs subtraction operation for the output signals OUT0-OUT3 using a subtraction output signal Sub as the result of the determination by the above logical expression. A selector SEL6 selects the resultant added or subtracted output signals OUT0-OUT3 using the addition output signal Add and the subtraction output signal Sub. More specifically, when 1 is added to the output signals OUT0-OUT3, the added results are output from the selectors SEL6. Contrarily, when 1 is subtracted from the output signals OUT0-OUT3, the subtracted results are output from the selectors SEL6.

Moreover, a selector SEL7 selects output signals S6O0-S6O3 of the selector SEL6 or the output signals OO0-OO3 of the FF circuits 30-33 using a Q output signal MS of a FF circuit 156. A data latch circuit 147 latches output signals S7O0-S7O3 of the selector SEL7 with a control signal CS2, and outputs the latched signals externally and also to the selectors SEL1-SEL3 as the signals OUT0-OUT3.

The signal MS goes low when a high-level pulse is given in the control signal START (i.e., at power-on and at forced operation), and thereafter goes high when the fifth rising pulse is given in the control signal CS1. Therefore, the selector SEL7 selects the output signals OO0-OO3 of the FF circuit 30-33 when the AD converter 1 is performing temperature measurement, and otherwise selects the output signals S6O0-S6O3 of the selector SEL6.

As in the first embodiment, the output signals OUT0-OUT3 latched by the data latch circuit 147 are decoded by the decoder DEC1, to prepare the signals S1-S3, which are used for the on/off control of the power supply switches 21-23 connected between the comparators 11-13 and the power supply VDD and the signal selection control of selecting the signals O1-O3 by the selector SEL4. The operation of the decoder DEC1 is naturally the same as that of the decoder DEC1 in the first embodiment.

As described above, in the control circuit 2 of the power control circuit 2 in the third embodiment, when the AD converter 1 is performing temperature measurement, the digital signals OO0-OO3 from the AD converter 1 are selected by the selector SEL7, and the selected digital signals OO0-OO3 are latched by the data latch circuit 147 with the control signal CS2 and output externally as the digital signals OUT0-OUT3.

Contrarily, when the AD converter 1 is not performing temperature measurement, the control circuit 2 of the power control circuit 2 performs the following control: the states of the digital signals OUT0-OUT3 after detection of a change in the comparator outputs are determined by computation, using the states of the digital signals OUT0-OUT3 before the detection of a change in the comparator outputs as references, based on the direction of the change of the potential of the analog voltage that is generated by the voltage generation circuit BGR1 and changes in association of the temperature.

### Fourth Embodiment

A semiconductor integrated circuit having an AD converter-equipped temperature sensor circuit of the fourth embodiment of the present disclosure will be described.

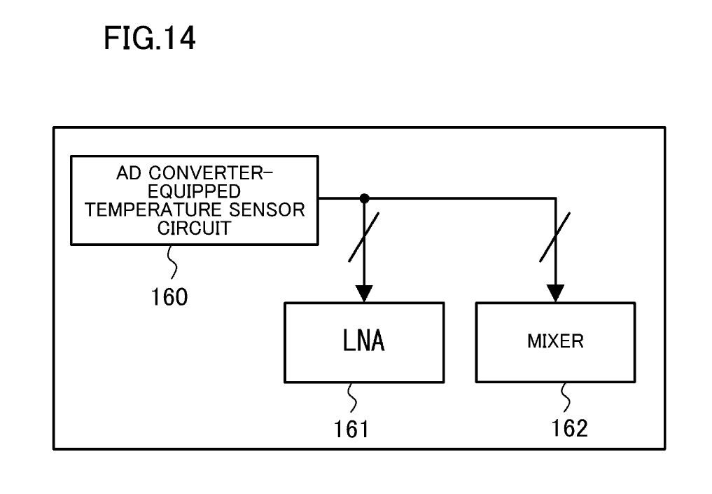

FIG. 14 shows a semiconductor integrated circuit having any of the AD converter-equipped temperature sensor circuit described in the first to third embodiment.

The semiconductor integrated circuit has an LNA 161 and a mixer 162 as high-frequency circuits. Characteristics of such high-frequency circuits 161 and 162 vary with the temperature and, in particular, tend to deteriorate under high temperature. In this embodiment, the digital signals OUT0-OUT3 AD-converted in an AD converter-equipped temperature sensor circuit 160 described in the first to third embodiment are input into the LNA 161 and the mixer 162. At the time of a temperature rise, drive currents to the LNA 161 and the mixer 162 are increased to correct the characteristics, thereby compensating the performance and thus preventing or decreasing variations in performance.

As described above, according to the present disclosure, in temperature sensing using an AD converter by detecting a change in a steady, slow-changing analog voltage, such as an analog voltage generated by a voltage generation circuit having temperature dependence, once temperature measurement is performed by operating the AD converter, power supply to a comparator other than comparators into which reference voltages upwardly and downwardly adjacent to the potential of the analog voltage are input is shut off, to allow only changes in the outputs of the comparators into which reference voltages upwardly and downwardly adjacent to the potential of the analog voltage are input to be detected. Therefore, power consumption can be reduced, and the signal processing time can be shortened. In particular, the present disclosure is very useful when being used in the semiconductor integrated circuit fields where operation is made with button batteries, etc. and low power is desired, such as the sensor network field.

What is claimed is:

1. An AD converter-equipped temperature sensor circuit, comprising:
a voltage generation circuit configured to generate an analog voltage dependent on temperature characteristics;
a successive approximation type AD converter having a plurality of comparators configured to compare the analog voltage received from the voltage generation circuit with a plurality of different reference voltages; and
a power control circuit configured to control the operation of the AD converter, wherein
the power control circuit performs temperature measurement by operating all the comparators of the AD converter, and, after determination of values of all bits of a digital signal of the AD converter, shuts off power supply to a comparator other than comparators into which reference voltages upwardly and downwardly adjacent to the potential of the analog voltage output from the voltage generation circuit are input, to detect a change in outputs of the comparators into which reference voltages upwardly and downwardly adjacent to the potential of the analog voltage are input.

2. The temperature sensor circuit of claim 1, wherein
when having detected a change in the outputs of the comparators into which reference voltages upwardly and downwardly adjacent to the potential of the analog voltage are input, the power control circuit supplies power to all the comparators of the AD converter to operate the comparators again, to determine the values of all bits of the digital signal.

3. The temperature sensor circuit of claim 1, wherein
the power control circuit increases the value of the digital signal by 1 when having detected a change in the output of the comparator into which a higher reference voltage out of the reference voltages upwardly and downwardly adjacent to the potential of the analog voltage is input, and decreases the value of the digital signal by 1 when having detected a change in the output of the comparator into which a lower reference voltage out of the reference voltages upwardly and downwardly adjacent to the potential of the analog voltage is input.

4. A semiconductor integrated circuit having the AD converter-equipped temperature sensor circuit of claim 1, comprising:
a high-frequency circuit,
wherein
the high-frequency circuit receives a temperature sensing signal from the AD converter-equipped temperature sensor circuit.

5. The semiconductor integrated circuit of claim 4, wherein
the high-frequency circuit is a low noise amplifier or a mixer.
